(19) United States
(12) Patent Application Publication
(10) Pub. No.: US 2014/0118949 A1
(43) Pub. Date: May 1, 2014

(54) CIRCUIT BOARD SYSTEM COMPRISING A SPRING FASTENED ELEMENT

(71) Applicant: TELLABS OY, Espoo (FI)

(72) Inventors: Antti HOLMA, Espoo (FI); Heikki JEKUNEN, Espoo (FI); Jari-Pekka LAIHONEN, Espoo (FI)

(73) Assignee: TELLABS OY, Espoo (FI)

(21) Appl. No.: 14/064,644

(22) Filed: Oct. 28, 2013

(30) Foreign Application Priority Data
Oct. 29, 2012 (FI) 20126120

(51) Int. Cl. H05K 7/12; H05K 7/20

(52) U.S. Cl. CPC H05K 7/12; H05K 7/20418
USPC 361/709; 361/748

(57) ABSTRACT

A circuit board system according to the invention includes a circuit board (101), an element (102) e.g. a heat sink mechanically supported with respect to the circuit board, and a spring-fastener (106) arranged to mechanically support the element. The spring-fastener includes a pressing portion pressing the element and a latching portion (107) extending from an end of the pressing portion and engaging with a securing member (108) that is fixed with respect to the circuit board. The latching portion is formed to constitute a loop (109) and the securing member extends through the loop. The loop is formed so that disengaging the latching portion from the securing member requires changing the shape of the loop against the spring-force of the material of the latching portion. Therefore, the risk of unintentional disengagement of the spring-fastener is reduced.

### FIELD OF THE INVENTION

The invention relates to a circuit board system comprising at least one element mechanically supported with a spring-fastener.

### BACKGROUND

A typical circuit board system comprises a circuit board furnished with electrical components. The circuit board comprises a body made of one or more layers of electrically insulating material and electrical conductors on one or both of the surfaces of the circuit board and/or between the layers of the electrically insulating material. Each of the electrical components can be, for example, an integrated circuit such as a processor or a memory, or a discrete component such as a resistor, a capacitor, an inductor, a transistor, or a diode. Furthermore, the circuit board system may comprise also other elements than electrical components. Examples of the other elements are heat sinks and mechanical support arms. Commonly used means for attaching elements such as heat sinks and mechanical support arms are spring-fasteners because they are relatively cost-effective and easy to assemble and disassemble.

Publication US20090154109 describes a circuit board system comprising a heat sink thermally contacted with an electronic component and a spring-fastener securing the heat sink to a circuit board. The spring-fastener comprises a pressing portion disposed on the heat sink and a pair of resilient latching portions extending from opposite ends of the pressing portion. Each latching portion is formed to constitute a hook for engaging with a corresponding securing member that is fixed with respect to the circuit board.

A circuit board system can be subjected to unintentional mechanical impacts in many situations, and there have been cases where a spring-fastener of the kind described above has been unintentionally disengaged when handling a circuit board system. Therefore, there is a need for secure spring-fasteners so as to minimize the risk of unintentional disengaging.

### SUMMARY

The following presents a simplified summary in order to provide a basic understanding of some aspects of various invention embodiments. The summary is not an extensive overview of the invention. It is neither intended to identify key or critical elements of the invention nor to delineate the scope of the invention. The following summary merely presents some concepts of the invention in a simplified form as a prelude to a more detailed description of exemplifying embodiments of the invention.

In accordance with the invention, there is provided a new circuit board system that can be, for example but not necessarily, a part of telecommunication equipment. A circuit board system according to the invention comprises:
a circuit board,
at least one element mechanically supported with respect to the circuit board, and
a spring-fastener arranged to mechanically support the at least one element with respect to the circuit board, the spring-fastener comprising a pressing portion pressing the at least one element and a latching portion extending from an end of the pressing portion and engaging with a securing member fixed with respect to the circuit board.

The above-mentioned latching portion is formed to constitute a loop and the securing member extends through the loop. The latching portion is formed to constitute the loop so that disengaging the latching portion from the securing member requires changing the shape of the loop against the spring-force of the material of the latching portion. The need to change the shape of the loop in order to disengage the spring-fastener reduces significantly the risk of unintentional disengagement of the spring-fastener.

The loop can be a closed loop so that a passage to and from the loop is closed when the shape of the loop is not changed by an external force, or the loop can be an open loop so that the passage to and from the loop is open but narrower than the thickness of the securing member when the shape of the loop is not changed by an external force.

It is also possible that the loop is an open loop so that the passage to and from the loop is not necessarily narrower than the thickness of the securing member but the passage can be positioned with respect to the securing member so that disengaging the latching portion from the securing member requires twisting the loop against the torsional spring-force of the material of the latching portion.

A number of non-limiting exemplifying embodiments of the invention are described in accompanied dependent claims.

Various non-limiting exemplifying embodiments of the invention both as to constructions and to methods of operation, together with additional objects and advantages thereof, will be best understood from the following description of specific exemplifying embodiments when read in connection with the accompanying drawings.

The verbs “to comprise” and “to include” are used in this document as open limitations that neither exclude nor require the existence of unrecited features. The features recited in depending claims are mutually freely combinable unless otherwise explicitly stated.

### BRIEF DESCRIPTION OF THE FIGURES

The exemplifying embodiments of the invention and their advantages are explained in greater detail below in the sense of examples and with reference to the accompanying drawings, in which:

FIGS. 1a and 1b illustrate a circuit board system according to an exemplifying embodiment of the invention,

FIG. 2 illustrates a detail of a circuit board system according to an exemplifying embodiment of the invention,

FIGS. 3a and 3b illustrate a detail of a circuit board system according to an exemplifying embodiment of the invention,

FIG. 4 illustrates a circuit board system according to an exemplifying embodiment of the invention, and

FIG. 5 illustrates a detail of a circuit board system according to an exemplifying embodiment of the invention.

### DESCRIPTION OF THE EXEMPLIFYING EMBODIMENTS

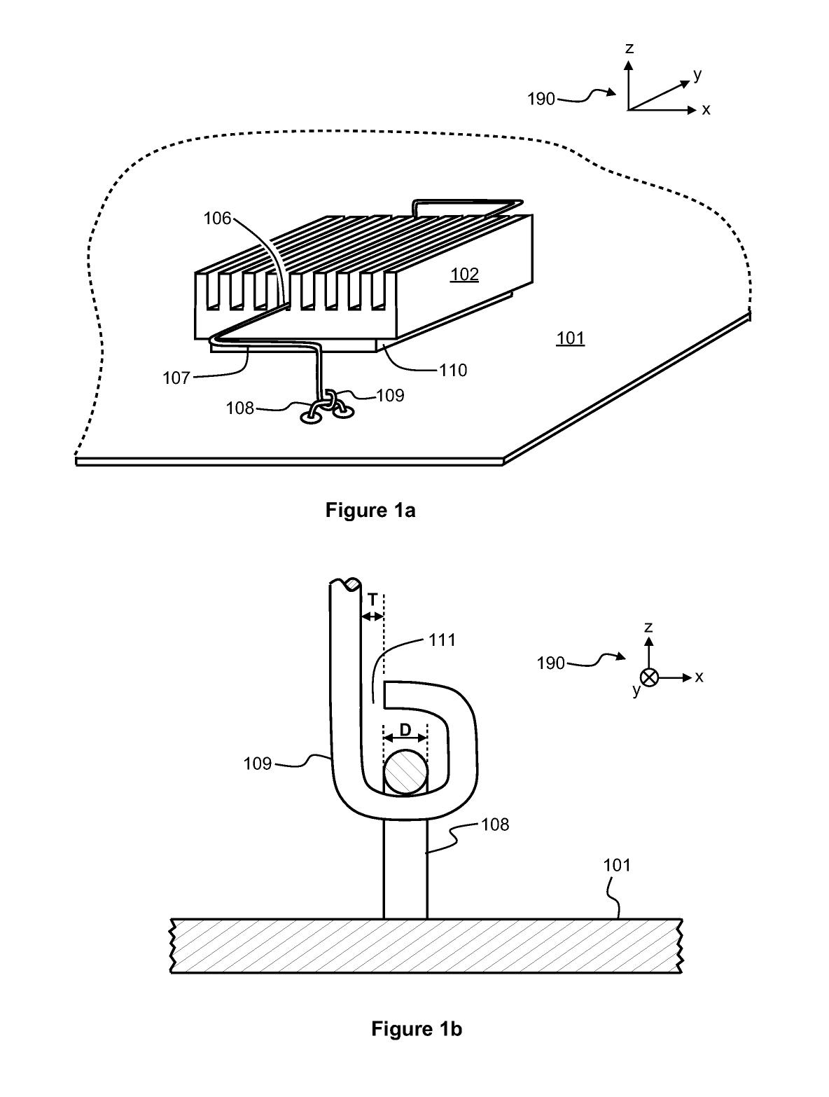

FIG. 1a shows a perspective view of a circuit board system according to an exemplifying embodiment of the invention. FIG. 1b shows view of a section taken from a detail of the circuit board system. The circuit board system comprises a circuit board 101 furnished with electrical components one of which is denoted with a reference number 110. The circuit board system can be, for example but not necessarily, a part of telecommunication equipment and it may comprise, for example, a processing system for supporting at least one of the following data transfer protocols: Internet Protocol “IP”, Ethernet protocol, MultiProtocol Label Switching “MPLS” protocol, Asynchronous Transfer Mode “ATM”.

The circuit board system comprises an element 102 that is mechanically supported with respect to the circuit board 101. In the exemplifying case illustrated in FIGS. 1a and 1b, the element 102 is a heat sink having a first surface in heat conducting relation with the electronic component 110 that is located between the heat sink and the circuit board 101. The circuit board system comprises a spring-fastener 106 that comprises a pressing portion pressing the heat sink against the electrical component 110 in the negative z-direction of a coordinate system 190. The spring-fastener 106 comprises a latching portion 107 that extends from an end of the pressing portion and is engaging with a securing member 108 mounted on the circuit board 101. The latching portion is formed to constitute a loop 109 and the securing member 108 extends through the loop as illustrated in FIGS. 1a and 1b. The latching portion is formed to constitute the loop 109 so that disengaging the latching portion 107 from the securing member 108 requires changing the shape of the loop 109 against the spring-force of the material of the latching portion. The need to change the shape of the loop for disengaging the spring-fastener reduces significantly the risk of unintentional disengagement of the spring-fastener. In the exemplifying case illustrated in FIGS. 1a and 1b, the spring-fastener 106 is made of wire of spring material, e.g. steel. The wire can be a round wire or, alternatively, the wire may have a non-circular cross-section. Correspondingly, the securing member 108 can be a piece of round wire as illustrated in the section view shown in FIG. 1b or, alternatively, the securing member may have a non-circular cross-section.

In the exemplifying case illustrated in FIGS. 1a and 1b, the latching portion of the spring-fastener is arranged to constitute the loop 109 so that a distance T from the tip of the latching portion to another section of the latching portion is less than the diameter D of the securing member 108 when the shape of the loop is not changed by an external force. The distance T and the diameter D are illustrated in FIG. 1b. In this exemplifying case, the loop 109 is an open loop so that the passage 111 to and from the loop is open but narrower than the thickness, i.e. the diameter D, of the securing member 108. As can be seen from FIGS. 1a and 1b, disengaging the spring-fastener 106 from the securing member 108 requires not only bending the pressing portion and/or the main part of latching portion of the spring-fastener but also changing the shape of the loop 109.

Only one end of the spring-fastener 106, i.e. the end comprising the latching portion 107, is visible in FIG. 1a. The other end of the spring-fastener comprises preferably a similar loop arrangement as the end comprising the latching portion 107. It is also possible that the other end of the spring-fastener comprises a different arrangement for engaging with the circuit board, e.g. an extension or a 90-degree bending securing to a suitably positioned slot of the circuit board.

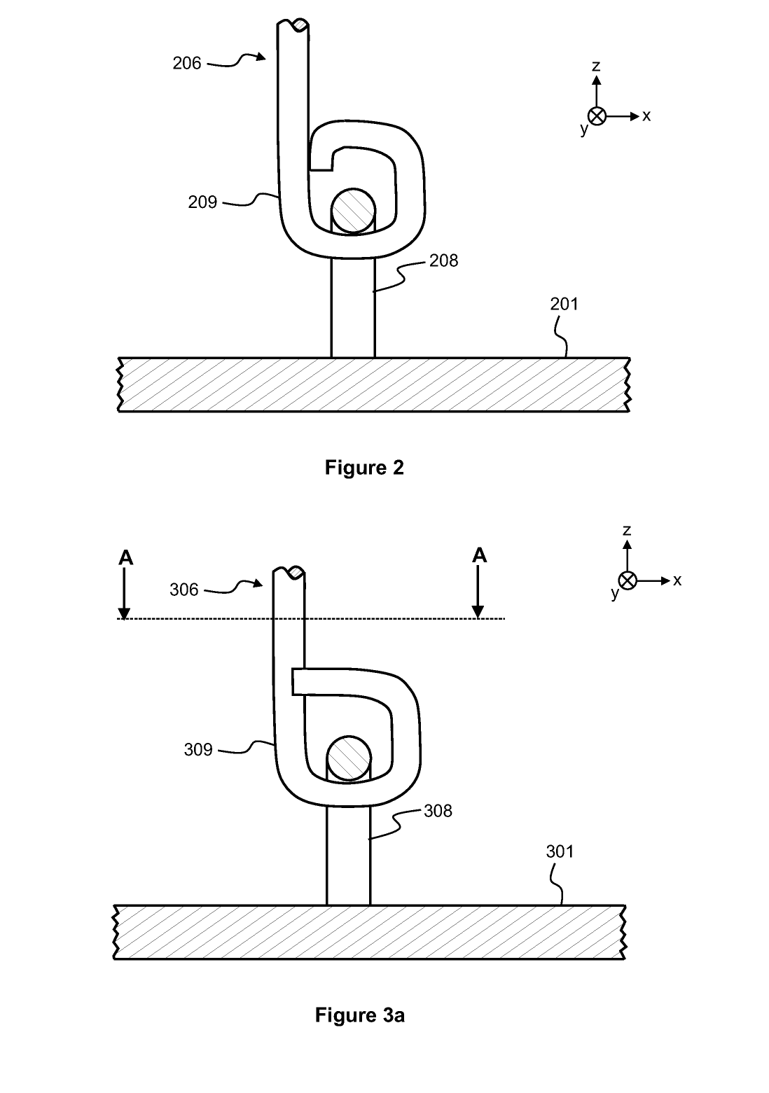

FIG. 2 shows view of a section taken from a detail of a circuit board system according to an exemplifying embodiment of the invention. The circuit board system comprises a circuit board 201, at least one element mechanically supported with respect to the circuit board, and a spring-fastener 206 arranged to mechanically support the at least one element with respect to the circuit board. The element mechanically supported with respect to the circuit board is not shown in FIG. 2. The spring-fastener 206 comprises a pressing portion pressing the at least one element and a latching portion extending from an end of the pressing portion and engaging with a securing member 208 mounted on the circuit board. In this exemplifying case, the latching portion of the spring-fastener is arranged to constitute a loop 209 so that the tip of the latching portion faces towards the circuit board 201 and a passage to and from the loop is capable of being widened by bending the tip of the latching portion towards the center of the loop. The fact that the tip of the latching portion is arranged to face towards the circuit board 201 in the way illustrated in FIG. 2 facilitates the installation of the spring-fastener 206.

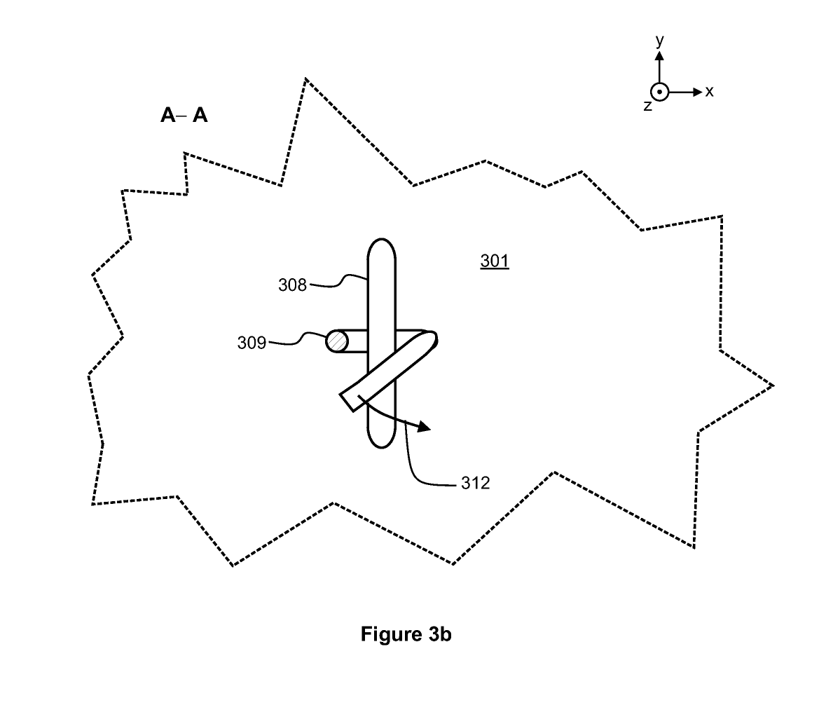

FIG. 3a shows view of a section taken from a detail of a circuit board system according to an exemplifying embodiment of the invention. FIG. 3b shows a view of a section taken along the line A-A shown in FIG. 3a. The circuit board system comprises a circuit board 301, at least one element mechanically supported with respect to the circuit board, and a spring-fastener 306 arranged to mechanically support the at least one element with respect to the circuit board. The element mechanically supported with respect to the circuit board is not shown in FIGS. 3a and 3b. The spring-fastener 306 comprises a pressing portion pressing the at least one element and a latching portion extending from an end of the pressing portion and engaging with a securing member 308 mounted on the circuit board. In this exemplifying case, the latching portion of the spring-fastener is arranged to constitute a loop 309 so that the spring-fastener 306 can be disengaged from the securing member 308 when the loop is twisted against torsional spring-force of the material of the latching portion. The twisting required to disengage the spring-fastener from the securing member 308 is illustrated with the arrow 312 shown in FIG. 3b.

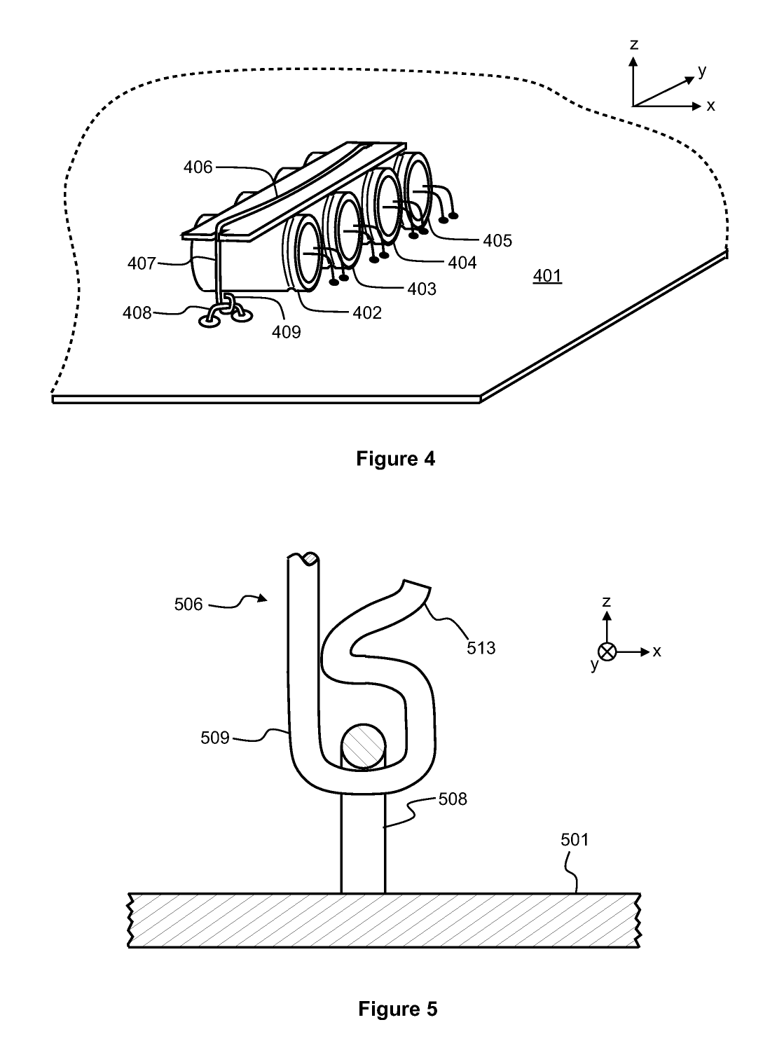

FIG. 4 illustrates a circuit board system according to an exemplifying embodiment of the invention. The circuit board system comprises a circuit board 401 and elements 402, 403, 404, and 405 that are mechanically supported with respect to the circuit board. In the exemplifying case illustrated in FIG. 4, the elements 402-405 are electrical components which are electrically connected to the circuit board with electrical wires. The electrical components can be, for example, electrolytic capacitors. The circuit board system comprises a spring-fastener 406 comprising a pressing portion that constitutes a part of a support arm system mechanically supporting the elements 402-405. The spring-fastener 406 comprises a latching portion 407 that extends from an end of the pressing portion and engages with a securing member 408 mounted on the circuit board. The latching portion is formed to constitute a loop 409 similar to that illustrated in FIGS. 1a and 1b. The latching portion 407 could as well be formed to constitute a loop similar to that illustrated in FIG. 2 or a loop similar to that illustrated in FIGS. 3a and 3b.

FIG. 5 shows view of a section taken from a detail of a circuit board system according to an exemplifying embodiment of the invention. The circuit board system comprises a circuit board 501, at least one element mechanically supported with respect to the circuit board, and a spring-fastener 506 arranged to mechanically support the at least one element with respect to the circuit board. The element mechanically supported with respect to the circuit board is not shown in FIG. 5. The spring-fastener 506 comprises a pressing portion pressing the at least one element and a latching portion extending from an end of the pressing portion and engaging with a securing member 508 mounted on the circuit board. In this exemplifying case, the latching portion of the spring-fastener is arranged to constitute a loop 509 so that the tip of the latching portion constitutes an opening arm 513 for opening the loop by twisting the opening arm.

In the above-presented exemplifying cases, the securing member that is fixed with respect to the circuit board is an arc-shaped element mounted on the circuit board at its both ends. However, it is also possible that the securing member is an isthmus that is between two apertures of the circuit board. The isthmus can be reinforced with a piece of metal wire embedded in the circuit board. Furthermore, it is also possible that the securing member is constituted by metal rod extending over an aperture of the circuit board and leaning on the edges of the aperture on an opposite side of the circuit board with respect to the spring-fastener.

The specific examples provided in the description given above should not be construed as limiting the applicability and/or the interpretation of the appended claims.

What is claimed is:

1. A circuit board system comprising:
a circuit board,
at least one element mechanically supported with respect to the circuit board, and
a spring-fastener arranged to mechanically support the at least one element with respect to the circuit board, the spring-fastener comprising a pressing portion pressing the at least one element and a latching portion extending from an end of the pressing portion and engaging with a securing member fixed with respect to the circuit board,
wherein the latching portion is formed to constitute a loop and the securing member extends through the loop, the latching portion being formed to constitute the loop so that disengaging the latching portion from the securing member requires changing the shape of the loop against spring-force of material of the latching portion.

2. A circuit board system according to claim 1, wherein the latching portion is arranged to constitute the loop so that a tip of the latching portion faces towards the circuit board and a passage to and from the loop is capable of being widened by bending the tip of the latching portion towards a center of the loop.

3. A circuit board system according to claim 1, wherein the latching portion is arranged to constitute the loop so that a distance (T) from a tip of the latching portion to another section of the latching portion is less than a diameter (D) of the securing member.

4. A circuit board system according to claim 1, wherein the latching portion is arranged to constitute the loop so that disengaging the latching portion from the securing member requires twisting the loop is against torsional spring-force of the material the latching portion.

5. A circuit board system according to claim 1, wherein the latching portion is arranged to constitute the loop so that a tip of the latching portion constitutes an opening arm for opening the loop by twisting the opening arm.

6. A circuit board system according to claim 1, wherein the element is a heat sink having a first surface in heat conducting relation with an electronic component between the heat sink and the circuit board, the pressing portion of the spring-fastener pressing the heat sink against the electronic component.

7. A circuit board system according to claim 2, wherein the element is a heat sink having a first surface in heat conducting relation with an electronic component between the heat sink and the circuit board, the pressing portion of the spring-fastener pressing the heat sink against the electronic component.

8. A circuit board system according to claim 3, wherein the element is a heat sink having a first surface in heat conducting relation with an electronic component between the heat sink and the circuit board, the pressing portion of the spring-fastener pressing the heat sink against the electronic component.

9. A circuit board system according to claim 4, wherein the element is a heat sink having a first surface in heat conducting relation with an electronic component between the heat sink and the circuit board, the pressing portion of the spring-fastener pressing the heat sink against the electronic component.

10. A circuit board system according to claim 5, wherein the element is a heat sink having a first surface in heat conducting relation with an electronic component between the heat sink and the circuit board, the pressing portion of the spring-fastener pressing the heat sink against the electronic component.

11. A circuit board system according to claim 1, wherein the at least one element is at least one electrical component electrically connected to the circuit board and the pressing portion of the spring-fastener constitutes at least a part of a support arm system mechanically supporting the at least one electrical component.

12. A circuit board system according to claim 2, wherein the at least one element is at least one electrical component electrically connected to the circuit board and the pressing portion of the spring-fastener constitutes at least a part of a support arm system mechanically supporting the at least one electrical component.

13. A circuit board system according to claim 3, wherein the at least one element is at least one electrical component electrically connected to the circuit board and the pressing portion of the spring-fastener constitutes at least a part of a support arm system mechanically supporting the at least one electrical component.

14. A circuit board system according to claim 4, wherein the at least one element is at least one electrical component electrically connected to the circuit board and the pressing portion of the spring-fastener constitutes at least a part of a support arm system mechanically supporting the at least one electrical component.

15. A circuit board system according to claim 5, wherein the at least one element is at least one electrical component electrically connected to the circuit board and the pressing portion of the spring-fastener constitutes at least a part of a support arm system mechanically supporting the at least one electrical component.

16. A circuit board system according to claim 11, wherein each of the at least one electrical component is an electrolytic capacitor.

17. A circuit board system according to claim 12, wherein each of the at least one electrical component is an electrolytic capacitor.

18. A circuit board system according to claim 13, wherein each of the at least one electrical component is an electrolytic capacitor.

19. A circuit board system according to claim 1, wherein the circuit board system comprises a processing system for supporting at least one of the following data transfer protocols: Internet Protocol “IP”, Ethernet protocol, MultiProtocol Label Switching “MPLS” protocol, Asynchronous Transfer Mode “ATM”.
